(19) United States
(12) Patent Application Publication
(10) Pub. No.: US 2026/0291845 A1
(43) Pub. Date: Sep. 24, 2026

(54) METHODS, SYSTEMS, AND COMPUTER READABLE MEDIA FOR DATA CENTER SWITCHING NETWORK PATH EMULATION IN AN ELECTRONICS DESIGN AUTOMATION (EDA) ENVIRONMENT

(71) Applicant: KEYSIGHT TECHNOLOGIES, INC., Santa Rosa, CA (US)

(72) Inventors: Alexandru Nicolae, Corbeanca (RO); Victor Stelian Alexe, Ploiesti (RO); Lucian Mogosanu, Bucharest (RO)

(21) Appl. No.: 19/083,409

(22) Filed: Mar. 18, 2025

(30) Foreign Application Priority Data
Mar. 14, 2025 (RO) A 2025 00097

(51) Int. Cl. H04L 43/20; G06F 30/20

(52) U.S. Cl. CPC H04L 43/20; G06F 30/20

(57) ABSTRACT

A method for impairments generation in an EDA test environment includes generating, by a traffic generator in a test platform including the traffic generator, an impairments module, and a virtIO network driver, test packets and transmitting the test packets to the impairments module. The method further includes controlling, by the impairments module, an impairment of the test packets. The method further includes transmitting, by the impairments module, to the virtIO network driver, and after controlling the impairment of the test packets, the test packets. The method further includes transmitting, by the virtIO network driver and to an EDA emulator, the test packets.

### PRIORITY CLAIM

This application claims the priority benefit of Romanian Patent Application No. (Serial No. not yet assigned), filed Mar. 14, 2025, and entitled, “METHODS, SYSTEMS, AND COMPUTER READABLE MEDIA FOR IMPAIRMENTS GENERATION IN ELECTRONICS DESIGN AUTOMATION (EDA) TEST ENVIRONMENT”, the disclosure of which is incorporated herein by reference in its entirety.

### TECHNICAL FIELD

The subject matter described herein relates to EDA testing. More particularly, the subject matter described herein relates to methods, systems, and computer readable media for impairments generation in an EDA test environment.

### BACKGROUND

Electronics design automation refers to the process of designing integrated circuits using software and firmware tools, such as logic design, synthesis, and verification tools, that are used to design and test a proposed integrated circuit before the design is committed to hardware. One type of tool used in EDA is referred to as an EDA emulator. An EDA emulator emulates a hardware design so that the functionality and performance of the design can be tested prior to finalizing the design in hardware. In some cases, an EDA emulator consists of two parts: a transactor and a design under test (DUT). The emulator is a system that is capable of loading and running ASIC designs in a form that resembles the final tapeout. The ASIC design running inside the emulator is called a design under test (DUT). The transactor is a component of the emulator that simulates an external I/O entity. This entity is usually connected to the DUT through a standard interface (e.g., PCIe or Ethernet). The DUT implements its own I/O logic, such as PCIe or Ethernet logic. The transactor may also simulate certain aspects of the external interface, such as L1 and L2 Ethernet logic. The transaction may also simulate characteristics of a bus or a wire that connects the external device and the DUT.

The DUT is the hardware definition language (HDL) implementation of the design being evaluated. For example, in computer networking, the DUT may be an implementation of a network chip, such as an Ethernet chip.

It is desirable to test an emulated electronics design under test under conditions that mimic the conditions that the design being evaluated will experience in operation. For example, if the emulated electronics design under test is a data center switching application specific integrated circuit (ASIC), then it may be desirable to generate and send emulated data center traffic to the design and monitor the performance of the design. The emulated data center traffic should include emulated impairments, such as delays, reordered packets, and dropped packets, that mimic the impairments that will be experienced by real traffic traversing a data center switching fabric. A test system that efficiently and accurately implements each of these impairments in an EDA test environment is needed.

In light of these and other difficulties, there exists a need for improved methods, systems, and computer readable media for impairments generation in an EDA test environment.

### SUMMARY

A method for impairments generation in an EDA test environment includes generating, by a traffic generator in a test platform including the traffic generator, an impairments module, and a virtual input/output (virtIO) network driver, test packets and transmitting the test packets to the impairments module. The method further includes controlling, by the impairments module, an impairment of the test packets. The method further includes transmitting, by the impairments module, to the virtIO network driver, and after controlling the impairment of the test packets, the test packets. The method further includes transmitting, by the virtIO network driver and to an EDA emulator, the test packets.

According to another aspect of the subject matter described herein generating the test packets includes generating emulated traffic of a data center processing an artificial intelligence/machine learning (AI/ML) workload.

According to another aspect of the subject matter described herein, controlling the impairment of the test packets includes instructing, by the impairments module, the traffic generator to drop at least one of the test packets.

According to another aspect of the subject matter described herein, controlling the impairment of the test packets includes reordering, by the impairments module, at least some of the test packets.

According to another aspect of the subject matter described herein, controlling the impairment of the test packets includes adding, by the impairments module, a timing impairment to the test packets.

According to another aspect of the subject matter described herein, adding the timing impairment to the test packets includes adjusting a packet inter-arrival time value carried by at least one of the test packets.

According to another aspect of the subject matter described herein, adding a timing impairment to the test packets includes adding a single rank timing impairment to the test packets.

According to another aspect of the subject matter described herein, adding a timing impairment to the test packets includes adding a distributed delay timing impairment to the test packets such that different delay values are added to test packets carrying different rank IDs.

According to another aspect of the subject matter described herein, the method for impairments generation in an EDA test environment includes controlling, by the impairments module, impairment of the packets received from the EDA emulator.

According to another aspect of the subject matter described herein, controlling, by the impairments module, impairment of the packets received from the EDA emulator includes instructing, by the impairments module, the virtIO network driver to drop at least one of the packets received from the EDA emulator and wherein the method further comprises, dropping, by the virtIO network driver, the at least one of the packets received from the EDA emulator.

According to another aspect of the subject matter described herein, a system for impairments generation in an electronics design automation (EDA) test environment is provided. The system includes a test platform including at least one processor and a memory. The system further includes a traffic generator implemented by the at least one processor for generating test packets. The system further includes a virtual input/output (virtIO) network driver implemented by the at least one processor for transmitting the test packets to an EDA emulator that emulates an electronics design under test and receiving packets from the electronics design under test. The system further includes an impairments module implemented by the at least one processor and between the traffic generator and the virtIO network driver that controls impairments of the test packets transmitted to the EDA emulator and the packets received from the EDA emulator.

According to another aspect of the subject matter described herein, in controlling the impairment of the test packets, the impairments module is configured to drop at least one of the test packets.

According to another aspect of the subject matter described herein, in controlling the impairment of the test packets the impairments module is configured to reorder at least some of the test packets.

According to another aspect of the subject matter described herein; in controlling the impairment of the test packets, the impairments module is configured to add a timing impairment to the test packets.

According to another aspect of the subject matter described herein, in adding the timing impairment to the test packets, the impairments module is configured to adjust a packet inter-arrival time value carried by at least one of the test packets.

According to another aspect of the subject matter described herein; in adding a timing impairment to the test packets, the impairments module is configured to add a single rank timing impairment to the test packets.

According to another aspect of the subject matter described herein; in adding a timing impairment to the test packets, the impairments module is configured to add a distributed delay timing impairment to the test packets such that different delay values are added to test packets carrying different rank IDs.

According to another aspect of the subject matter described herein, the impairments module is configured to control impairment of the packets received from the EDA emulator.

According to another aspect of the subject matter described herein, in controlling impairment of the packets received from the EDA emulator, the EDA emulator is configured to instruct the virtIO network driver to drop at least one of the packets received from the EDA emulator and the virtIO network driver is configured to drop the at least one of the packets received from the EDA emulator.

According to another aspect of the subject matter described herein, a non-transitory computer readable medium having stored thereon executable instructions that when executed by a processor of a computer control the computer to perform steps is provided. The steps include generating, by a traffic generator in a test platform including the traffic generator, an impairments module, and a virtual input/output (virtIO) network driver, test packets and transmitting the test packets to the impairments module. The steps further include controlling, by the impairments module, the impairment of the test packets. The steps further include transmitting, by the impairments module, to the virtIO network driver, and after controlling the impairment of the test packets, the test packets. The steps further include transmitting, by the virtIO network driver and to the EDA emulator, the test packets. The steps further include transmitting, by the virtIO network driver and to the EDA emulator, the test packets.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a readable computer medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIG. 1 is a block diagram illustrating an exemplary system for impairments generation in an EDA test environment;

FIG. 2 is a block diagram illustrating the configuration and use of an impairments module to cause a packet generator to drop packets in a packet flow sent to an EDA emulator;

FIG. 3 is a block diagram illustrating the configuration and use of an impairments module to reorder packets transmitted to an EDA emulator;

FIG. 4 is a block diagram illustrating the configuration and use of impairments module to adjust delay between packets transmitted to an EDA emulator;

FIG. 5 illustrates exemplary computer code for hooking in functions defined in an impairments module to insert impairments in generated network traffic;

FIG. 6 is a block diagram illustrating the configuration and use of an impairments module to cause the virtIO network driver to drop packets received from an EDA emulator;

FIG. 7 is a block diagram illustrating an exemplary test platform on which an endpoint VM may execute; and

FIG. 8 is a flow chart illustrating an exemplary process for impairments generation in an EDA test environment.

### DETAILED DESCRIPTION

The subject matter described herein is intended for use with a DUT implemented by an EDA emulator, which is configured to test a pre-silicon chip design. A pre-silicon chip design is an HDL-implemented version of a chip design that needs to be tested for functionality and performance before committing the design to hardware. An EDA emulator executes the chip emulation using a clock local to the emulator. The clock local to the emulator provides a timing domain that is referred to herein as the EDA emulator time domain.

As stated above, one key need of EDA emulation platforms is the ability to test a pre-silicon chip design with realistic network traffic associated with high-performance distributed processing tasks, such as artificial intelligence/machine learning (AI/ML) workload tasks. Such testing requires coordination between test traffic generators, AI/ML workload simulators, and the EDA emulator.

The subject matter described herein achieves robust testing of an electronics design under test by using network test system components to handle the complexities involved in generating high-fidelity packet traffic that is representative of AI/ML workload processing in a realistic/complex distributed computing environment (i.e., environments that include complex switching fabrics/topologies, complex congestion control mechanisms, realistic impairment mechanisms, etc.) and further allows EDA platform users to easily manipulate AI/ML workload configurations (e.g., collective communication strategies, distributed processor models/types, switching fabric types and attributes, etc.).

In the validation of high-performance computing fabrics, incorporating traffic impairments into testing is critical. These impairments (delays, packet drops, reordering, jitter, corruption) play an essential role in simulating real-world network conditions. By including impairments in the traffic generation process, engineers can more effectively test and validate the resilience, fault tolerance, and recovery mechanisms of fabric elements under diverse operational conditions.

Fabric elements rely on error recovery protocols like remote direct memory access (RDMA) retransmission or priority-based flow control (PFC) to ensure reliable data delivery. Traffic impairments provide a controlled environment to evaluate how these mechanisms respond under stress.

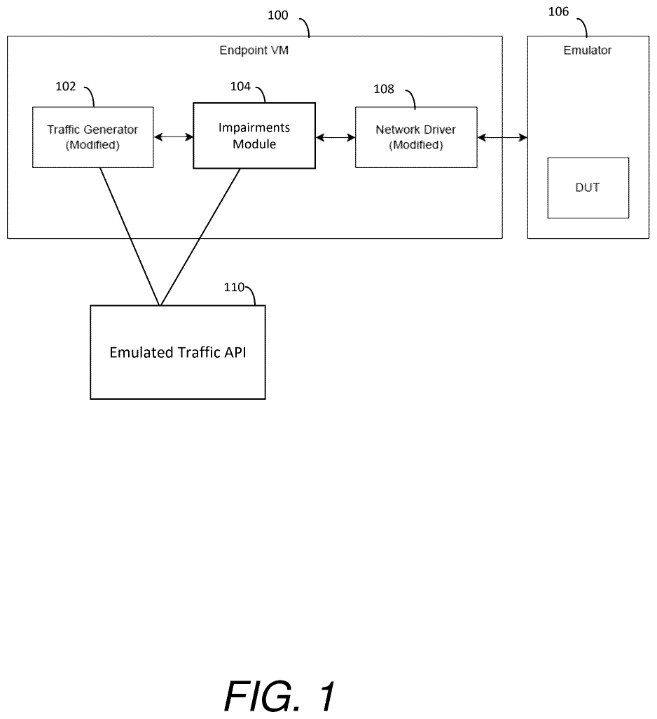

The subject matter described herein includes an impairments module implemented inline between network traffic generators and an EDA design under test to add impairments to generated traffic and provide the impaired traffic to the EDA design under test. FIG. 1 is a block diagram illustrating an exemplary architecture for impairments generation in an EDA design under test. Referring to FIG. 1, the architecture may be implemented in one or more endpoint virtual machines (VMs), such as endpoint VM 100, that provides access to virtual processing and memory resources. Endpoint VM 100 includes a traffic generator 102 that generates emulated network traffic, such as emulated datacenter traffic related to processing of an AI/ML workload. In one example, the emulated datacenter traffic may include emulated RDMA over converged Ethernet version 2 (RoCE) traffic related to an AI/ML workload.

Endpoint VM 100 further includes an impairments module 104 located in line between traffic generator 102 and an EDA emulator 106, which emulates an electronics design under test. Impairments module 104 is configurable to implement impairments scenarios on both transmit (towards EDA emulator 106) and receive (from EDA emulator 106). In one implementation, impairments module 104 intercepts the packets that are sent to, and received from, EDA emulator 106, adds impairments to the packets, and transmits the impaired packets to EDA emulator 106 or traffic generator 102. As such, bidirectional traffic flow can be altered to achieve different impairment scenarios. Endpoint VM 100 further includes a modified virtual input/output (VirtIO) network driver 108 that interfaces directly with EDA emulator 106 and impairments module 104. VirtIO network driver 108 is a para-virtualized driver that provides network interface card (NIC) functionality to endpoint VM 100. VirtIO network driver 108 is modified so that the packets (which contain data and emulator metadata) received and sent by the endpoint VM 100 pass through the impairments module 104.

An emulated traffic API 110 may reside on the same or a separate computing platform from endpoint VM 100 and may allow a user to configure traffic generation. Emulated traffic API 110 allows for a variety of impairment settings to be merged into an impairment profile, which VM endpoints, such as endpoint VM 100, can be used to configure impairments module 104 to provide simulated packet drops, delays or reordering. In one example, there are three impairment settings that can each be individually enabled to form a variety of profiles. These settings are:
TX/RX Packet Drops;
TX packet shuffling; and
TX delay.
   Emulated traffic API 110 allows a user to combine these impairment settings, and, as such, various combinations of impairment scenarios are possible. For example, combinations include TX/RX packet drops combined with TX packet shuffling and/or TX packet delay.

As indicated above, one type of packet impairment that may be configured is packet drops. Configuring packets drop is done by providing the following fields inside the emulated traffic API 110:
Packet Type: Defines the packet (or list of packets) to which the drop impairment should apply.
Direction: TX/RX.
Drop After: Integer value. each match of ‘Packet Type’ decreases this counter.
Drop Count: Integer value. Once ‘Drop After’ reaches 0, apply the drop impairment to the next ‘Drop Count’matches

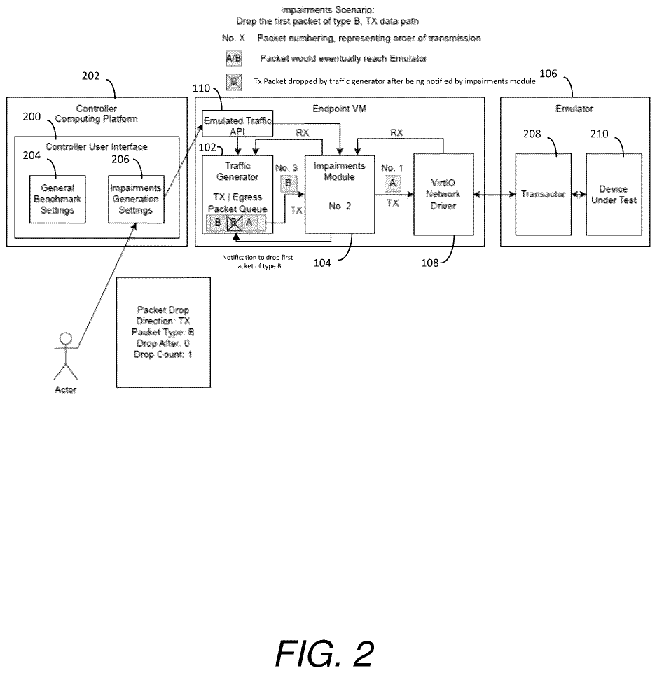

FIG. 2 is a block diagram illustrating the use of emulated traffic API 110 to configure impairments module 104 to cause traffic generator 102 to drop packets on the transmit side. In FIG. 2, a user or actor accesses a controller user interface 200 that resides on a controller computing platform 202 to configure general benchmark settings 204 and impairment generation settings 206. The impairment generation settings 206 include configuration instructions that cause impairments module 104 to notify traffic generator 102 to drop packets of a specific type in the transmit direction. Other configuration settings include the number of packets to wait before beginning the packet drop and the number of packets to drop. Impairments generation settings 206 are provided to impairments module 104 using emulated traffic API 110. Impairments generation settings 206 cause impairments module 104 to notify traffic generator 102 to drop the first packet of type B of the packets generated by traffic generator 102. Traffic generator 102 drops the first packet of type B and transmits the remaining packets to EDA emulator 106 via impairments module 104 and virtIO network driver 108. A transactor 208 of EDA emulator 106 receives the packets and provides the packets to EDA device under test 210.

Another impairment that may be added to emulated data center traffic shuffling or re-ordering of packets from the order in which the packets are generated by traffic generator 102. In one example, emulated traffic API 110 may allow a user to generate a range of packets to which re-ordering is applied using the following fields:
Start: Integer value. The packet number since the start of transmission from which the shuffling should start.
Stop: Integer value. The packet number since the start of transmission from which the shuffling should stop.
   This impairment setting causes impairments module 104 to shuffle packets in the range [Start, Stop].

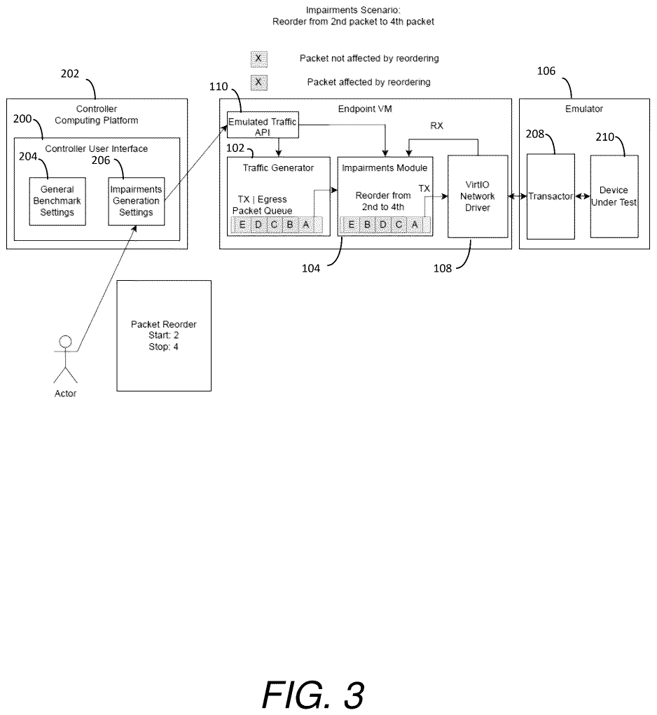

FIG. 3 is a block diagram illustrating the configuration and use of an impairments module to reorder packets transmitted to an EDA emulator. Referring to FIG. 3, a user provides impairments generation settings 206 to impairments module 104 via emulated traffic API 110 to instruct impairments module 104 to start reordering packets at packet 2 and end reordering packets at packet 4. Traffic generator 102 generates packets in the order ABCDE. Traffic generator 102 transmits the packet sequence to impairments module 104. Impairments module 104 receives the sequence of packets and reorders the 2nd through 4th packet from BCD to CDB. Impairments module 104 transmits the reordered packets to virtIO network driver 108, which transmits the packets to EDA emulator 106.

Yet another type of impairment that may be added to emulated data center traffic by impairments module 104 is delay. Emulated traffic API 110 may allow a user to configure transmit packet delay in two forms, single-rank and distributed. Single-rank delay affects a single endpoint VM, while distributed applies to all endpoint VMs. Rank is a term that refers to the rank of a processor performing an AI/ML processing task. Traffic generator 102 generates emulated data center traffic with packets having different rank values carried in the traffic. Emulated traffic API 110 may allow a user to configured single-rank delay, using the following fields:
Rank ID: Integer value. Specify the unique identifier of the endpoint VM that takes part in traffic generation.
Delay_us: Integer value. Specify the time, in microseconds, that the ‘Rank ID’ transmitted packets should be delayed by.

Thus, a user may configure impairments module 104 to add impairments to packets carrying specific rank IDs. The user may configure impairments module 104 to impair packets carrying different rank IDs differently. For example, the user may configure impairments module 104 to apply different delays to test packets with different rank IDs.

Distributed delay is more complex, specifying a continuous probability distribution by which the delay should be applied. To configure distributed delay, emulated traffic API 110 may provide the following fields:
Distribution Type: Defines the probability distribution. (e.g., Gaussian)
Mean_us: Integer value. Specify the mean of the probability distribution
Stddev_us: Integer value. Specify the standard deviation of the probability distribution

Thus, a user may configure a Gaussian probability distribution used to set delay values for test packets. For each test packet received, impairments module 104 may select, from the Gaussian distribution, a delay value and apply the delay value to the test packet by changing the value of a packet inter-frame gap (IFG) carried by the test packet.

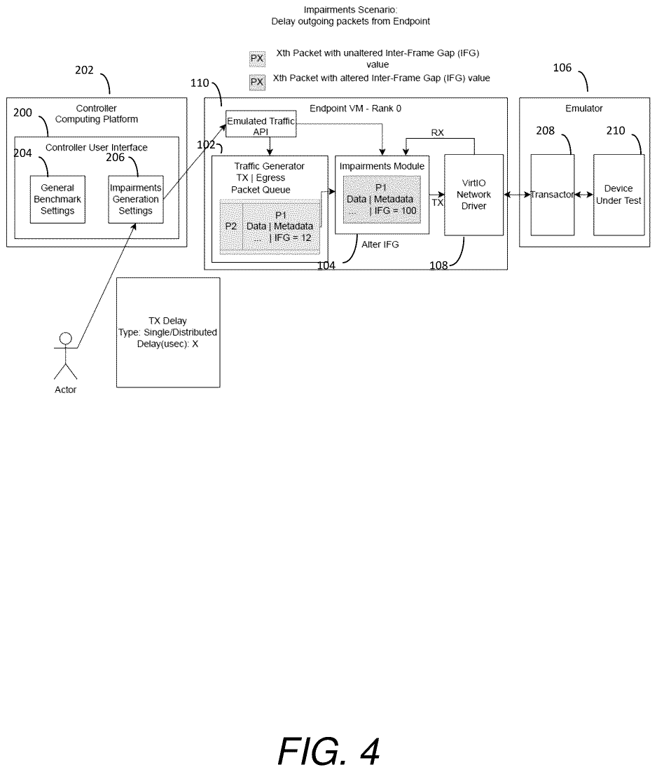

FIG. 4 is a block diagram illustrating the use of emulated traffic API 110 to configure impairments module 104 to adjust delay between packets transmitted to EDA emulator 106. Referring to FIG. 4, a user provides impairment generation settings 206 to impairments module 104 that configures impairments module 104 to delay packets transmitted to emulator 106. In the illustrated example, the user configures the type of delay, i.e., single or distributed, and the amount of delay in microseconds. Impairments module 104 implements the delay in packets transmitted to emulator 106 by altering the IFG value carried in one of the packets to simulate delayed transmission of a packet in a packet flow. In the illustrated example, impairments module 104 alters the interframe gap value in a received packet to be equal to 100. Impairments module 104 transmits the packet with the altered inter frame gap value to emulate or 106 via virtIO network driver 108. Emulator 106 receives the packet and provides the packet to EDA device under test 210.

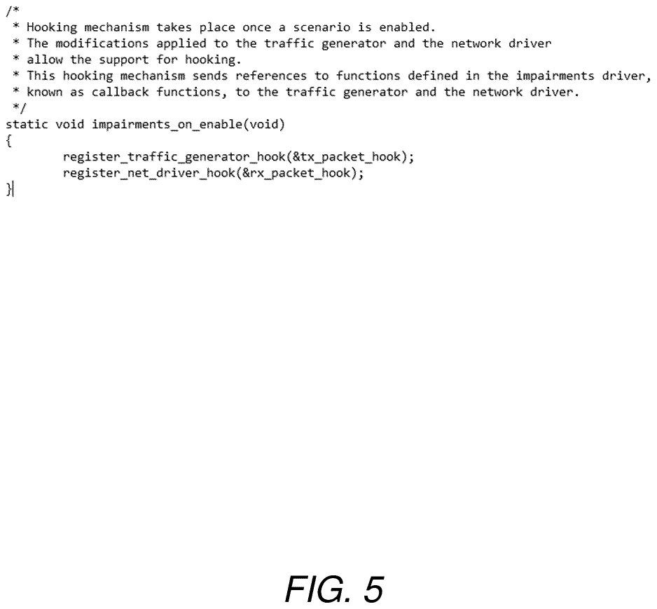

To implement the delay impairments, timing metadata is added to or altered in the emulated packets. When an impairment profile is selected by the client, impairments module 104 of each endpoint VM 100 is enabled, thus hooking into the modified network driver that supports emulator specific metadata. FIG. 5 illustrates exemplary computer code for hooking in functions defined in impairments module 104 to insert impairments in generated network traffic. The computer code sends references to traffic generator 102 and virtIO network driver 108 that cause traffic generator 102 and virtIO network driver 108 to execute callback functions defined in impairments module 104 that add impairments to emulated network traffic generated by traffic generator 102.

The hooking of impairments module 104 into traffic generator 102 and virtIO network driver 108 allows back and forth communication between impairments module 104 and traffic generator 102 and between impairments module 104 and virtIO network driver 108. As such, impairments module 104 is responsible for notifying traffic generator 102 and virtIO network driver 108, in the case of a packet drop, whether a current network packet should be dropped or not. On the transmit side, i.e., towards EDA emulator 106, a packet drop is achieved by impairments module 104 notifying traffic generator 102 that the current packet should be dropped, and traffic generator 102 drops the identified packet or packets. On the receive side, i.e., towards traffic generator 102, a packet drop is achieved by impairments module 104 notifying virtIO network driver 108 that the current packet should be dropped, and virtIO network driver 108 drops the identified packet or packets.

Transmit traffic reordering is achieved by buffering packets inside of impairments module 104 and sending them to virtIO network driver 108 in an order that follows a certain index list or based on distribution curves, e.g., Gaussian. As illustrated by the example in FIG. 3, impairments module 104 buffers packets received from traffic generator 102, reorders packets within the reordering configuration range input by the user, and transmits the reordered packets to virtIO network driver 108.

Impairments module 104 may also implement impairments on the receive side, i.e., packets transmitted by DUT 210, before transmitting the packets to traffic generator 102. Impairments may be implemented on the receive side in the same way that impairments are implemented on the transmit side (see examples in FIGS. 2-4). To implement a delay or reordering impairment on the receive side, impairments module 104 buffers packets received from virtIO network driver 108. Impairments module 104 then impairs the packets, e.g., by delaying packets and/or reordering packets (see FIGS. 2-4) and transmits the impaired packets to traffic generator 102. To implement a drop impairment on the receive side, impairments module 104 notifies virtIO network driver 108 of the packets that should be dropped, and virtIO network driver 108 drops the corresponding packets.

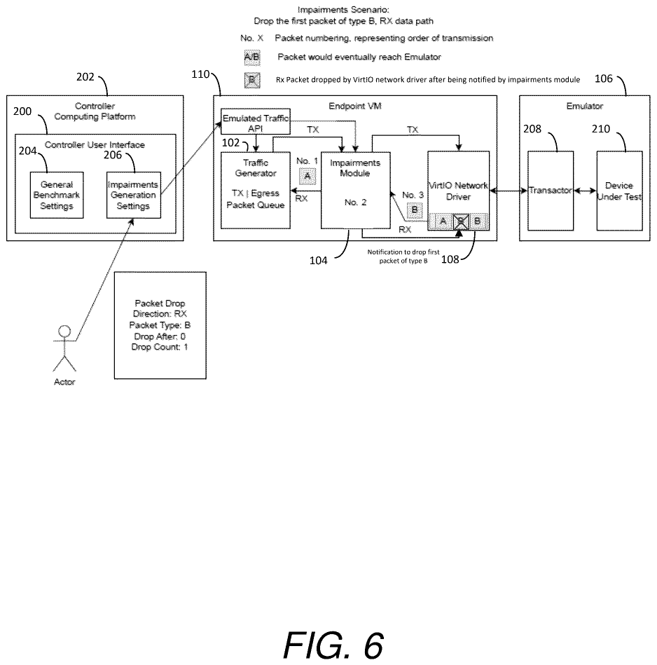

FIG. 6 is a block diagram illustrating the use of emulated traffic API 110 to configure impairments module 104 to cause virtIO network driver 108 to drop packets on the receive side. In FIG. 6, a user or actor accesses a controller user interface 200 that resides on controller computing platform 202 to configure general benchmark settings 204 and impairment generation settings 206. Impairment generation settings 206 include configuration instructions that instruct impairments module 104 to notify virtIO network driver 108 to drop packets of a specific type in the receive direction. Other configuration settings include the number of packets to wait before beginning the packet drop and the number of packets to drop. Impairments generation settings 206 are provided to impairments module 104 using emulated traffic API 110. Impairments generation settings 206 cause impairments module 104 notify virtIO network driver 108 to drop the first packet of type B of the packets received from emulator 106. Device under test 210 transmits packets of a specified type to virtIO network driver 108 via transactor 208. The packets transmitted by device under test 210 may be response packets to test packets transmitted by traffic generator 102 or packets transmitted by traffic generator 102 after being routed or switched by device under test 210. VirtIO network driver 108 receives the packets from emulator 106, buffers the packets, drops the first packet of type B, and transmits the remaining packets to traffic generator 102 via impairments module 104.

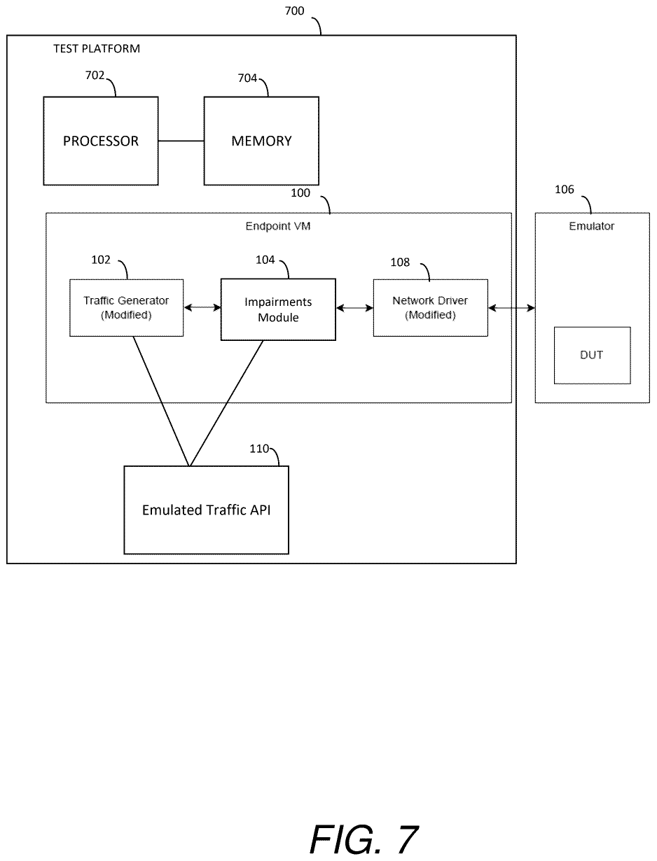

FIG. 7 is a block diagram illustrating an exemplary test platform on which endpoint VM 100 may execute. Referring to FIG. 7, a test platform 700 includes at least one processor 702 and memory 704. Endpoint VM 100 provides a virtualized environment in which traffic generator 102, impairments module 104, and virtIO network driver 108 may execute. Endpoint VM 100, traffic generator 102, impairments module 104, virtIO network driver 108, and emulated traffic API 110 may be implemented using computer executable instructions stored in memory 704 and executed by processor 702.

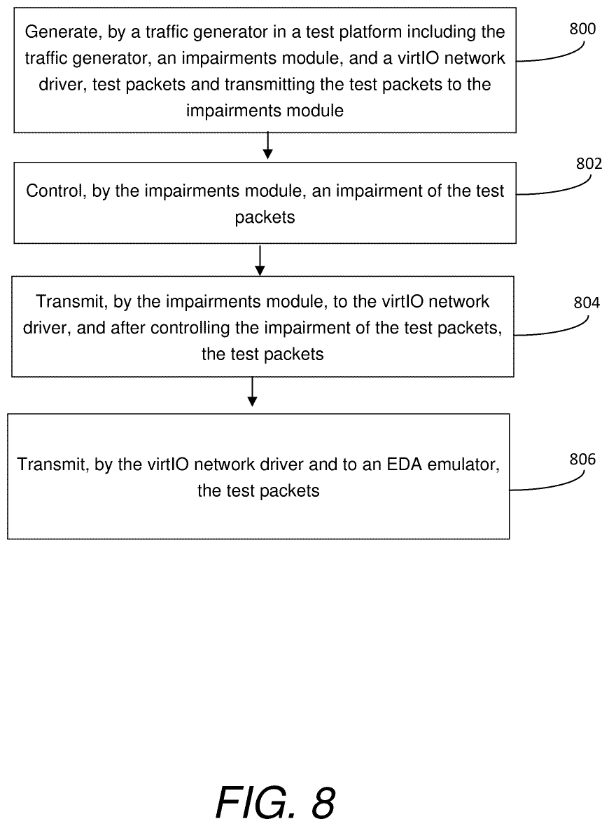

FIG. 8 is a flow chart illustrating an exemplary process for impairments generation in an EDA test environment. Referring to FIG. 8, in step 800, the process includes generating, by a traffic generator in a test platform including the traffic generator, an impairments module, and a VirtIO network driver, test packets and transmitting the test packets to the impairments module. For example, a traffic generator, such as traffic generator 102, may generate test packets to testing an electronics design under test implemented by an EDA emulator.

In step 802, the process further includes controlling, by the impairments module, an impairment of the test packets. For example, an impairments module, such as impairments module 104 may cause test packets to be dropped, delayed, and/or reordered.

In step 804, the process further includes transmitting, by the impairments module, to the virtIO network driver, and after controlling the impairment of the test packets, the test packets. For example, an impairments module, such as impairments module 104 may transmit impaired test packets to virtIO network driver 108.

In step 806, the process further includes transmitting, by the virtIO network driver and to an EDA emulator, the test packets. For example, a network driver, such as virtIO network driver 108, may transmit impaired test packets to the EDA emulator, which provides the test packets to the electronics design under test being emulated by the EDA emulator.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for impairments generation in an electronics design automation (EDA) test environment, the method comprising:
generating, by a traffic generator in a test platform including the traffic generator, an impairments module, and a virtual input/output (virtIO) network driver, test packets and transmitting the test packets to the impairments module;
controlling, by the impairments module, an impairment of the test packets;
transmitting, by the impairments module, to the virtIO network driver, and after controlling the impairment of the test packets, the test packets; and
transmitting, by the virtIO network driver and to an EDA emulator, the test packets.

2. The method of claim 1 wherein generating the test packets includes generating emulated traffic of a data center processing an artificial intelligence/machine learning (AI/ML) workload.

3. The method of claim 1 wherein controlling the impairment of the test packets includes instructing, by the impairments module, the traffic generator to drop at least one of the test packets.

4. The method of claim 1 wherein controlling the impairment of the test packets includes reordering, by the impairments module, at least some of the test packets.

5. The method of claim 1 wherein controlling the impairment of the test packets includes adding, by the impairments module, a timing impairment to the test packets.

6. The method of claim 5 wherein adding the timing impairment to the test packets includes adjusting a packet inter-arrival time value carried by at least one of the test packets.

7. The method of claim 5 wherein adding a timing impairment to the test packets includes adding a single rank timing impairment to the test packets.

8. The method of claim 5 wherein adding a timing impairment to the test packets includes adding a distributed delay timing impairment to the test packets such that different delay values are added to test packets carrying different rank IDs.

9. The method of claim 1 comprising controlling, by the impairments module, impairment of the packets received from the EDA emulator.

10. The method of claim 9 wherein controlling, by the impairments module, impairment of the packets received from the EDA emulator includes instructing, by the impairments module, the virtIO network driver to drop at least one of the packets received from the EDA emulator and wherein the method further comprises, dropping, by the virtIO network driver, the at least one of the packets received from the EDA emulator.

11. A system for impairments generation in an electronics design automation (EDA) test environment, the system comprising:
a test platform including at least one processor and a memory;
a traffic generator implemented by the at least one processor for generating test packets;
a virtual input/output (virtIO) network driver implemented by the at least one processor for transmitting the test packets to an EDA emulator that emulates an electronics design under test and receiving packets from the electronics design under test; and
an impairments module implemented by the at least one processor and between the traffic generator and the virtIO network driver for controlling impairments of the test packets transmitted to the EDA emulator and the packets received from the EDA emulator.

12. The system of claim 11 wherein, in controlling the impairment of the test packets, the impairments module is configured to drop at least one of the test packets.

13. The system of claim 11 wherein, in controlling the impairment of the test packets the impairments module is configured to reorder at least some of the test packets.

14. The system of claim 11 wherein, in controlling the impairment of the test packets, the impairments module is configured to add a timing impairment to the test packets.

15. The system of claim 14 wherein, in adding the timing impairment to the test packets, the impairments module is configured to adjust a packet inter-arrival time value carried by at least one of the test packets.

16. The system of claim 14 wherein, in adding a timing impairment to the test packets, the impairments module is configured to add a single rank timing impairment to the test packets.

17. The system of claim 14 wherein, in adding a timing impairment to the test packets, the impairments module is configured to add a distributed delay timing impairment to the test packets such that different delay values are added to test packets carrying different rank IDs.

18. The system of claim 11 wherein the impairments module is configured to control impairment of the packets received from the EDA emulator.

19. The system of claim 18 wherein, in controlling impairment of the packets received from the EDA emulator, the EDA emulator is configured to instruct the virtIO network driver to drop at least one of the packets received from the EDA emulator and the virtIO network driver is configured to drop the at least one of the packets received from the EDA emulator.

20. A non-transitory computer readable medium having stored thereon executable instructions that when executed by a processor of a computer control the computer to perform steps comprising:
generating, by a traffic generator in a test platform including the traffic generator, an impairments module, and a virtual input/output (virtIO) network driver, test packets and transmitting the test packets to the impairments module;
controlling, by the impairments module, an impairment of the test packets;
transmitting, by the impairments module, to the virtIO network driver, and after controlling the impairment of the test packets, the test packets; and
transmitting, by the virtIO network driver and to an electronics design automation (EDA) emulator, the test packets.
